(19) United States
(12) Patent Application Publication
(10) Pub. No.: US 2006/0276021 A1
(43) Pub. Date: Dec. 7, 2006

(54) Method for forming metal line of semiconductor device

(76) Inventor: Jeong Seong Hee, Namdong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/445,525

(22) Filed: Jun. 2, 2006

(30) Foreign Application Priority Data
Jun. 2, 2005 (KR) 10-2005-0047137

(51) Int. Cl. H01L 21/44

(52) U.S. Cl. 438/597

(57) ABSTRACT

A method for forming a metal line of a semiconductor device includes: forming an insulating layer on a substrate; sequentially forming a first barrier metal layer and a metal layer on the insulating layer; forming a second barrier metal layer on the metal layer; coating a photoresist on the second barrier metal layer and patterning the coated photoresist; exposing the first barrier metal layer by sequentially removing the second barrier metal layer and the metal layer using the patterned photoresist as a mask; removing the patterned photoresist; and removing the exposed first barrier metal layer using the second barrier metal layer and the metal layer as a mask.

### FIELD OF THE INVENTION

The present invention relates to a method for forming a metal line of a semiconductor device, and more particularly, to a method for forming a metal line of a semiconductor device, which can improve stabilization of a line forming process and yield of the semiconductor device.

### BACKGROUND OF THE INVENTION

Metallization is a process of connecting elements of a semiconductor device using small resistors, that is, a process of forming a contact portion for connecting a chip to internal circuits of a package. Metal for the metallization should have good adhesion property with respect to a silicon oxide layer, a silicon thin film, and/or other materials used in semiconductor devices, and should also have temperature and stress resistance.

In addition, the metal for the metallization should have small ohmic contact resistance, should react with silicon for good ohmic contact property with respect to internal circuits, and should have high conductivity.

When the metallization is performed using a metal satisfying the above conditions, it should provide strong resistance to forming an open circuit of metal line, which is caused by corrosion, oxidation, electron migration, and stress migration.

As an example of such a metal having a strong resistance to forming an open circuit, aluminum has good adhesive force with respect to silicon, silicon oxide layer, and other such materials, and has good ohmic contact property with respect to heavily doped n+ and p+ silicon. Also, aluminum has low resistivity of about 2.7 μΩ-cm and is cheaper than other noble metals. Because of these advantages, aluminum is widely used for a metal line.

However, as semiconductor devices such as DRAM become highly integrated, a line width of the metal line decreases. Thus, when electrons are moving through an aluminum line, they can collide with aluminum ions, causing an open circuit of the metal line.

Generally, an aluminum layer is deposited using sputtering. Such an aluminum layer can have defects such as hillocks or dislocations and degradation of electrical properties due to electron migration and other forces.

After depositing aluminum alloy, an annealing process is performed typically in a range of 400-450° C. During the annealing process, non-uniform diffusion of silicon into an aluminum layer occurs in a contact surface between a silicon substrate and an aluminum layer.

Consequently, silicon is consumed and thus a contact area is reduced. In addition, the aluminum layer that penetrates into the silicon layer is formed in a spike shape so as to fill an empty space of the non-uniformly diffused aluminum. Because a high electric field is applied in the spike portion, the contact can be broken. This phenomenon increases leakage current, resulting in characteristic degradation.

A related art method for forming a metal line of a semiconductor device will be described below.

FIGS. 1A to 1C are sectional views illustrating a related art method for forming a metal line of a semiconductor device.

Referring to FIG. 1A, an insulating layer 12 is formed on a semiconductor substrate 11, and a first Ti/TiN layer 13 is formed on the insulating layer 12. Then, an aluminum layer 14 is deposited on the first Ti/TiN layer 13.

Next, a second Ti/TiN layer 15 is formed on the aluminum layer 14, and a photoresist 16 is coated on the second Ti/TiN layer 15. A line region is defined by selectively patterning the photoresist 16 using exposure and development processes.

Referring to FIG. 1B, the second Ti/TiN layer 15, the aluminum layer 14, and the first Ti/TiN layer 13 are simultaneously etched using the patterned photoresist 16 as a mask. As a result, an aluminum line 20 having a desired width is formed.

Referring to FIG. 1C, the patterned photoresist 16 used as the mask is removed.

Although not shown, an interlayer insulating layer can be formed on the entire surface of the semiconductor substrate 11 having the aluminum line 20 and then can be selectively removed to form a via hole. Another aluminum line can be formed to electrically connect to the aluminum line 20 through the via hole.

However, the related art method has the following problems.

Particles are generated during the process of etching the second Ti/TiN layer, the aluminum layer, and the first Ti/TiN layer using the patterned photoresist as the mask to form the aluminum line. Due to the particles, the reliability of the line is degraded and the yield of the semiconductor device is reduced.

### SUMMARY OF THE INVENTION

Accordingly, the present invention is directed to a method for forming a metal line of a semiconductor device that can address one or more problems due to limitations and disadvantages of the related art.

An object of the present invention is to provide a method for forming a metal line of a semiconductor device, which can improve the reliability of line and the yield of the semiconductor device by minimizing the generation of particles during a line forming process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for forming a metal line of a semiconductor device, including: forming an insulating layer on a substrate; forming a first barrier metal layer and a metal layer on the insulating layer, sequentially; forming a second barrier metal layer on the metal layer; coating a photoresist on the second barrier metal layer and patterning the coated photoresist; exposing the first barrier metal layer by sequentially removing the second barrier metal layer and the metal layer using the patterned photoresist as a mask; removing the patterned photoresist; and removing the exposed first barrier metal layer using the second barrier metal layer and the metal layer as a mask.

In another aspect of the present invention, a method for forming a metal line of a semiconductor device, including: forming-an-insulating layer on a substrate; performing plasma treatment on the insulating layer; forming a metal layer on the plasma-treated insulating layer; forming a barrier metal layer on the metal layer; coating a photoresist on the barrier metal layer and patterning the coated photoresist; removing the barrier metal layer and the metal layer using the patterned photoresist as a mask, sequentially; and removing the patterned photoresist and irradiating ultraviolet light.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1C are sectional views illustrating a related art method for forming a metal line of a semiconductor device;

FIGS. 2A to 2D are sectional views illustrating a method for forming a metal line of a semiconductor device according to an embodiment of the present invention; and

FIGS. 3A to 3D are sectional views illustrating a method for forming a metal line of a semiconductor device according to another embodiment of the present invention.

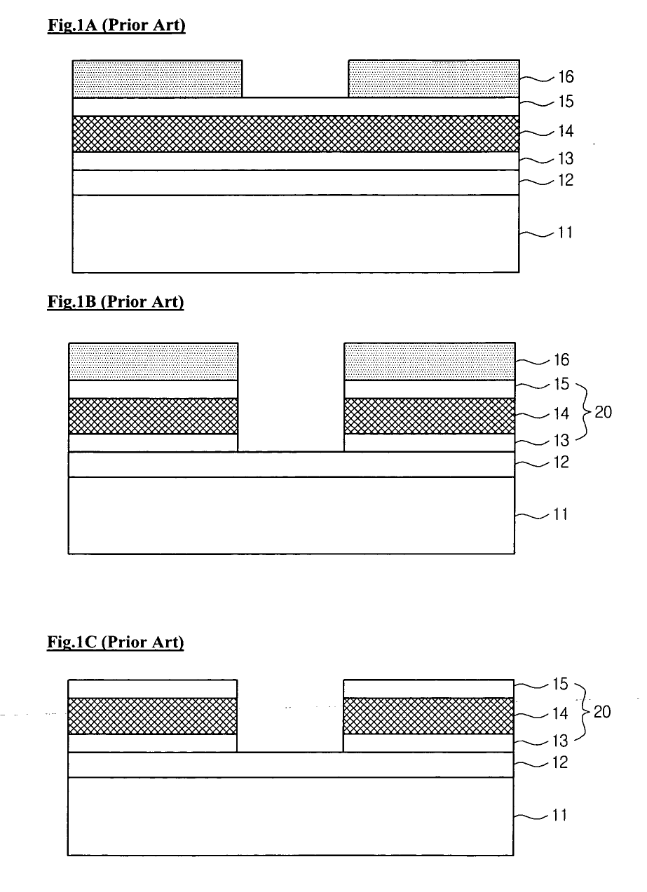

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

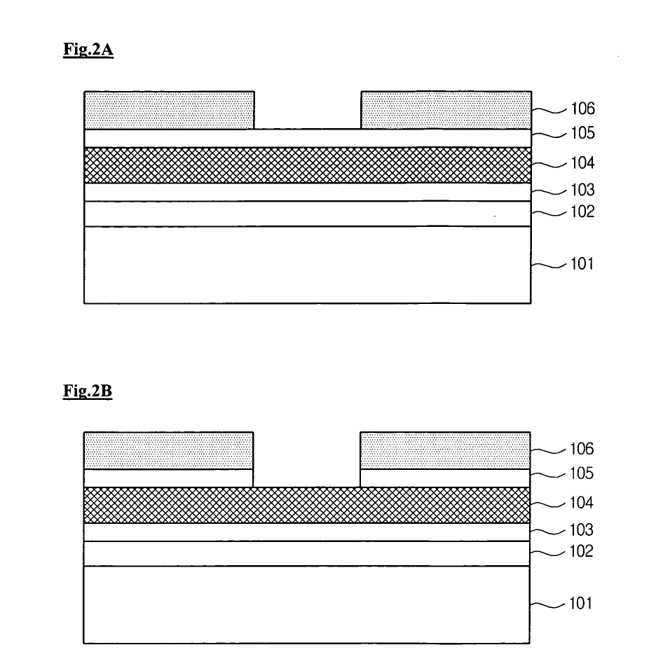

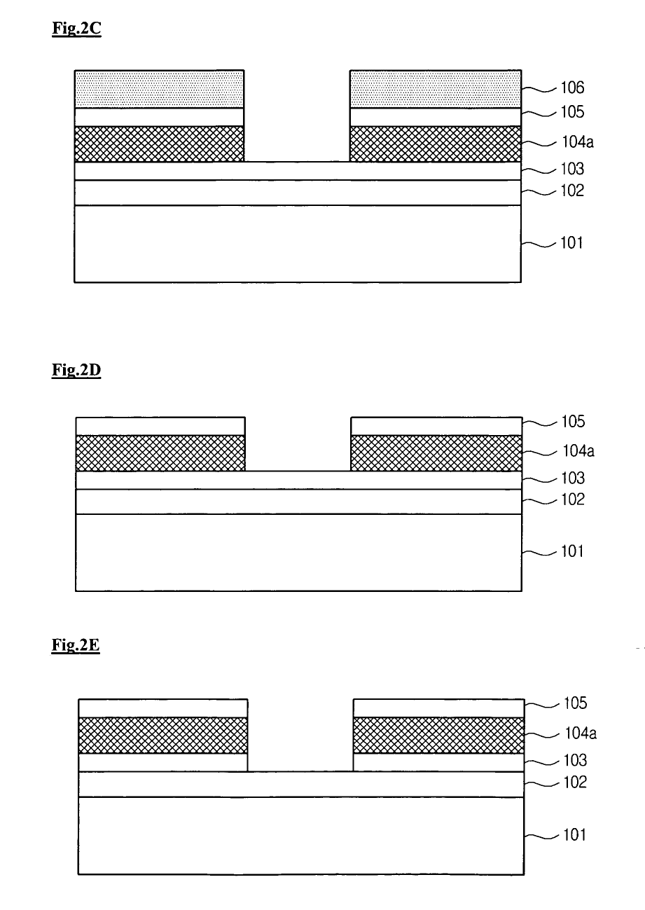

FIGS. 2A to 2D are sectional views illustrating a method for forming a metal line of a semiconductor device according to an embodiment of the present invention.

Referring to FIG. 2A, an insulating layer 102 is formed on a semiconductor substrate 101, and a first Ti/TiN layer 103 is formed on the insulating layer 102. Then, an aluminum layer 104 is deposited on the first Ti/TiN layer 103.

The aluminum layer 104 can be deposited using for example, a physical vapor deposition (PVD) process, a chemical vapor deposition (CVD) process, or a sputtering deposition process.

Next, a second Ti/TiN layer 105 is formed on the aluminum layer 104, and a photoresist 106 is coated on the second Ti/TiN layer 105

In an embodiment, the second Ti/TiN layer 105 is thicker than the first Ti/TiN layer 103. In a specific embodiment, the second Ti/TiN layer 105 is at least two times the thickness of the first Ti/TiN layer 103. A line region is defined by selectively patterning the photoresist 106 using exposure and development processes.

Referring to FIG. 2B, the second Ti/TiN layer 105 is selectively removed using the patterned photoresist 106 as a mask.

In an embodiment, the second Ti/TiN layer 105 can be etched in the conditions of pressure of 5-15 mT, etch gas of 80-90(sccm)BCl₃, source power of 100-400 W, and bias power of 800-1200 W.

Referring to FIG. 2C, the aluminum layer 104 is selectively removed using the patterned photoresist 106 as a mask, thereby forming an aluminum line 104a.

In an embodiment, the aluminum layer 104 can be etched in the conditions of pressure of 5-15 mT, etch gas of 50-60(sccm)Cl₂+30-40(sccm)Ar+1-10(sccm)CHF₃, source power of 100-370 W, and bias power of 800-1200 W.

Referring to FIG. 2D, the photoresist 106 can be removed using an O₂ ashing process.

In one embodiment, the remaining particles can be removed by selectively performing an ultraviolet (UV) irradiation process.

Then, the exposed first Ti/TiN layer 103 can be removed while performing plasma RIE to remove the second Ti/TiN layer 105 by a predetermined thickness. Because the second Ti/TiN layer 105 is thicker than the first Ti/TiN layer 103, a thickness of the second Ti/TiN layer 105 remains on the aluminum layer during the removing process of the first Ti/TiN layer 103.

Particles generated during the process of etching the aluminum layer 104 can be removed when the first and second Ti/TiN layers 103 and 105 are selectively etched. In addition, the residue of the photoresist 106 can also be removed.

In one embodiment, After the RIE process of etching the first Ti/TiN layer 103, an UV irradiating process can be selectively performed to remove the remaining particles.

In a specific embodiment, using the etch selectivity of the aluminum layer 104 and the first and second Ti/TiN layers 103 and 105, the aluminum layer 104 can be selectively removed using the photoresist 106 as a mask, thereby forming the aluminum line 104a. Then, the particles and the residue of the photoresist 106 can be removed while removing the second Ti/TiN layer 105 by a predetermined thickness using the plasma etching process.

In an embodiment, the first Ti/TiN layer 103 can be etched in the conditions of pressure of 5-15 mT, etch gas of 35-45(sccm)BCl₃+15-25(sccm)Ar+1-15(sccm)CHF₃, source power of 100-370 W, and bias power of 600-1000 W. Although the aluminum layer 140 has been described as one embodiment of the present invention, a metal layer formed of material selected from W, TiN, Ti, Cu, and alloy thereof can also be used.

In embodiments, the first and second Ti/TiN layers 103 and 105 can be deposited as barrier metal layers using a PVD process or CVD process. TiN, Ta, TaN, WNₓ, and TiAl(N) can also be used for the first and second Ti/TiN layers 103 and 105.

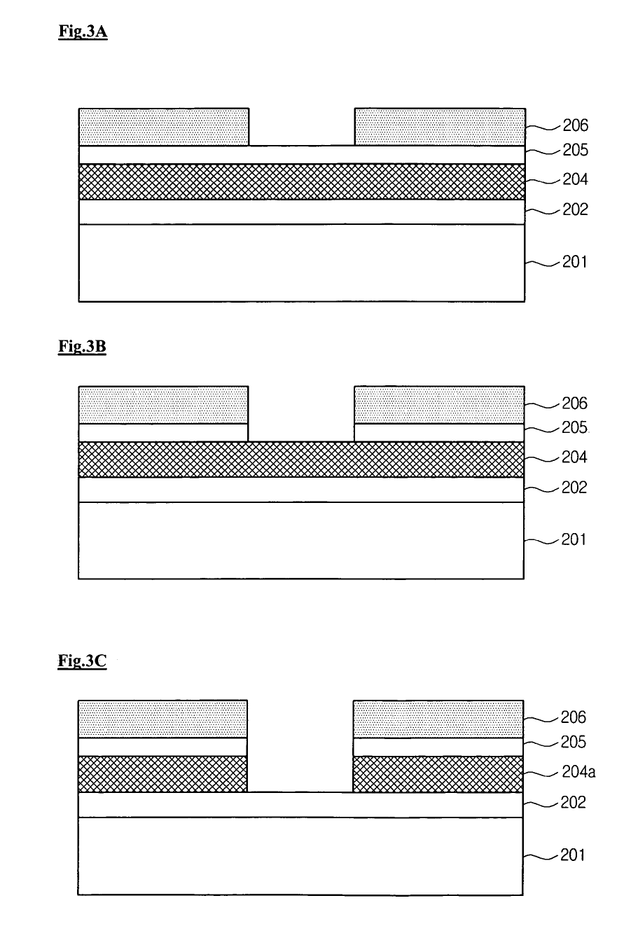

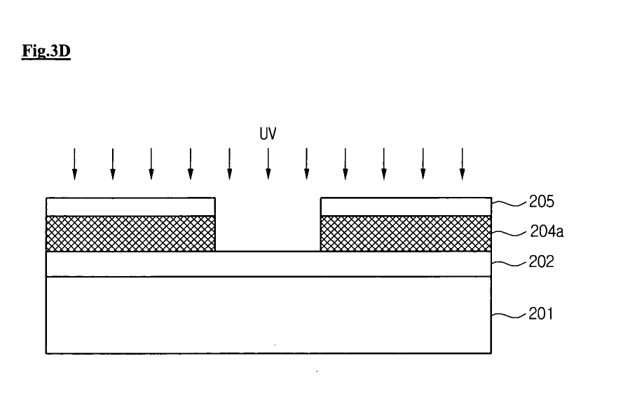

FIGS. 3A to 3D are sectional views illustrating a method for forming a metal line of a semiconductor device according to another embodiment of the present invention.

Referring to FIGS. 3A to 3D, an insulating layer 202 is formed on a semiconductor substrate 201, and a plasma treatment can be performed to increase the adhesive force with respect to aluminum. The plasma treatment is a process of increasing the adhesive force with respect to the aluminum or other metals by changing the surface of the insulating layer 202 into a hydrophobic or hydrophilic state.

Next, an aluminum layer 204 is deposited on the insulating layer 202, and a Ti/TiN layer 205 is formed on the aluminum layer 204. A photoresist 206 is coated on the Ti/TiN layer 205 and then is patterned.

Although a bi-layered structure of the aluminum layer 204 and the Ti/TiN layer 205 has been described, any process of forming a metal line by etching one or more metal layers can be applied.

Since a process of forming an insulating layer and a metal layer in FIGS. 3A to 3D can be performed identical to that described in reference to FIGS. 2A to 2D, a detailed description thereof will be omitted.

Referring to FIG. 3B, the Ti/TiN layer 205 is selectively removed using the patterned photoresist 206 as a mask. In an embodiment, the Ti/TiN layer 205 can be etched in the conditions of pressure of 5-15 mT, etch gas of 80-90(sccm)BCl₃, source power of 100-400 W, and bias power of 800-1200 W.

Referring to FIG. 3C, the aluminum layer 204 is selectively removed using the patterned photoresist 206 as a mask, thereby forming an aluminum line 204a.

In an embodiment, the aluminum layer 204 can be etched in the conditions of pressure of 5-15 mT, etch gas of 50-60(sccm)Cl₂+30-40(sccm)Ar+1-10(sccm)CHF₃, source power of 100-370 W, and bias power of 800-1200 W.

Referring to FIG. 3D, the photoresist 206 can be removed using an O₂ ashing process. The remaining particles can be removed from the semiconductor substrate 201 by selectively performing an ultraviolet (UV) irradiation process. A quantity of the UV light can be adjusted according to size of the particles.

In such an embodiment, the particles and the residue of the photoresist 206, which are generated during the etching process, can be removed by performing the UV irradiation process.

Then, in an embodiment, the Ti/TiN layer 205 can be etched in the conditions of pressure of 5-15 mT, etch gas of 35-45(sccm)BCl₃+15-25(sccm)Ar+1-15(sccm)CHF₃, source power of 100-370 W, and bias power of 600-1000 W.

Although the aluminum layer 204 has been described as one embodiment of the present invention, a metal layer formed of material selected from W, TiN, Ti, Cu, and alloy thereof can also be used.

In embodiments, the Ti/TiN layer 205 can be deposited as a barrier metal layer using a PVD process or CVD process. TiN, Ta, TaN, WNₓ, and TiAl(N) can also be used in place of the Ti/TiN layer 205.

As described above, after the photoresist is removed, the Ti/TiN layer can be removed by a predetermined thickness. Then, the particles generated during the process of forming the metal line can be removed through the UV irradiation process treatment, thereby improving the reliability of the line and the yield of the semiconductor device.

It will be apparent to those skilled in the art that various modifications and variations can be made in the present invention. Thus, it is intended that the present invention covers the modifications and variations of this invention provided they come within the scope of the appended claims and their equivalent.

I claim:

1. A method for forming a metal line of a semiconductor device, comprising:
forming an insulating layer on a substrate;
forming a first barrier metal layer and a metal layer on the insulating layer, sequentially;
forming a second barrier metal layer on the metal layer;
forming a photoresist layer on the second barrier metal layer and patterning the photoresist layer;
exposing the first barrier metal layer by sequentially removing the second barrier metal layer and the metal layer using the patterned photoresist as a mask;
removing the patterned photoresist; and
removing the exposed first barrier metal layer using the second barrier metal layer and the metal layer as a mask.

2. The method according to claim 1, wherein the second barrier metal layer is thicker than the first barrier metal layer.

3. The method according to claim 2, wherein the second barrier metal layer is at least two times thicker than the first barrier metal layer.

4. The method according to claim 1, wherein the first and second barrier metal layers are formed of material selected from the group consisting of Ti/TiN, TiN, Ta, TaN, WNₓ, and TiAl(N).

5. The method according to claim 1, wherein the second barrier metal layer is etched in the conditions of pressure of 5-15 mT, etch gas of 80-90(sccm)BCl₃, source power of 100-400 W, and bias power of 800-1200 W.

6. The method according to claim 1, wherein the metal layer is etched in the conditions of pressure of 5-15 mT, etch gas of 50-60(sccm)Cl₂+30-40(sccm)Ar+1-10(sccm)CHF₃, source power of 100-370 W, and bias power of 800-1200 W.

7. The method according to claim 1, wherein the first barrier metal layer is etched in the conditions of pressure of 5-15 mT, etch gas of 35-45(sccm)BCl₃+15-25(sccm)Ar+1-15(sccm)CHF₃, source power of 100-370 W, and bias power of 600-1000 W.

8. The method according to claim 1, further comprising performing an ultraviolet irradiating process.

9. The method according to claim 8, wherein the ultraviolet irradiating process is performed after removing the patterned photoresist.

10. The method according to claim 8, wherein the ultraviolet irradiating process is performed after removing the exposed first barrier metal layer.

11. The method according to claim 1, wherein the metal layer is formed of metal selected from the group consisting of Al, W, TiN, Ti, Cu, and alloy thereof.

12. A method for forming a metal line of a semiconductor device, comprising:
forming an insulating layer on a substrate;
performing a plasma treatment to the insulating layer;
forming a metal layer on the plasma-treated insulating layer;
forming a barrier metal layer on the metal layer;
forming a photoresist layer on the barrier metal layer and patterning the photoresist layer;
removing the barrier metal layer and the metal layer using the patterned photoresist as a mask, sequentially;
removing the patterned photoresist; and
performing an ultraviolet light irradiating process.

13. The method according to claim 12, wherein performing a plasma treatment changes a top surface of the insulating layer into a hydrophobic or hydrophilic state so as to increase an adhesive force with respect to the metal layer.

14. The method according to claim 12, wherein the barrier metal layer is formed of metal selected from the group consisting of Ti/TiN, TiN, Ta, TaN, WNₓ, and TiAl(N).

15. The method according to claim 12, wherein the barrier metal layer is etched in the conditions of pressure of 5-15 mT, etch gas of 80-90(sccm)BCl₃, source power of 100-400 W, and bias power of 800-1200 W.

16. The method according to claim 12, wherein the metal layer is etched in the conditions of pressure of 5-15 mT, etch gas of 50-60(sccm)Cl₂+30-40(sccm)Ar+1-10(sccm)CHF₃, source power of 100-370 W, and bias power of 800-1200 W.

17. The method according to claim 12, wherein the barrier metal layer is etched in the conditions of pressure of 5-15 mT, etch gas of 35-45(sccm)BCl₃+15-25(sccm)Ar+1-15(sccm)CHF₃, source power of 100-370 W, and bias power of 600-1000 W.
